(19) United States
(12) Patent Application Publication
(10) Pub. No.: US 2011/0073176 A1
(43) Pub. Date: Mar. 31, 2011

(54) SOLAR CELL AND METHOD FOR MANUFACTURING THE SAME

(75) Inventor: Hyun-Jong KIM, Seoul (KR)

(73) Assignee: SAMSUNG ELECTRONICS CO., LTD., Suwon-si (KR)

(21) Appl. No.: 12/719,259

(22) Filed: Mar. 8, 2010

(30) Foreign Application Priority Data
Sep. 29, 2009 (KR) 10-2009-0092429

(51) Int. Cl. H01L 31/0216; H01L 31/18

(52) U.S. Cl. 136/256; 438/98; 257/E31.12

(57) ABSTRACT

A solar cell includes a semiconductor substrate including; a p-type layer, and an n-type layer disposed adjacent to the p-type layer, a dielectric layer positioned on one surface of the semiconductor substrate, a protective layer positioned on one surface of the dielectric layer, a first electrode electrically connected to the p-type layer of the semiconductor substrate and a second electrode electrically connected to the n-type layer of the semiconductor substrate.

This application claims priority to Korean Patent Application No. 10-2009-0092429, filed on Sep. 29, 2009, and all the benefits accruing therefrom under 35 U.S.C. §119, the content of which in its entirety is herein incorporated by reference.

### BACKGROUND OF THE INVENTION

1. Field of the Invention

This disclosure relates to a solar cell and a method of manufacturing the same.

2. Description of the Related Art

A solar cell is a photoelectric conversion device that transforms electromagnetic energy, typically solar energy, into electrical energy. Solar cells have attracted much attention lately as a renewable and pollution-free next generation energy source.

A typical solar cell includes p-type and n-type semiconductors and produces electrical energy by transferring electrons and holes to the n-type and p-type semiconductors, respectively, and then collecting electrons and holes in opposing electrodes adjacent to the semiconductors when an electron-hole pair (“EHP”) is produced by solar light energy absorbed in a photoactive layer inside the semiconductors.

Furthermore, a typical solar cell is designed to gain as much efficiency as possible for producing electrical energy from input solar energy. In order to increase the efficiency of a solar cell, research has sought to increase the number of electron-hole pairs produced in a semiconductor, and to decrease a loss of a resultant charge withdrawn from the solar cell.

A significant amount of the charge generated in a typical solar cell is lost due to recombination of the produced electrons and holes outside of the electrodes. Accordingly, various methods of preventing such recombination have been suggested.

### BRIEF SUMMARY OF THE INVENTION

One aspect of this disclosure provides a highly efficient solar cell having excellent durability and a long life span.

Another aspect of this disclosure provides a method of manufacturing the solar cell which has good mass-productivity.

According to one aspect of this disclosure, an embodiment of a solar cell is provided that includes; a semiconductor substrate including; a p-type layer and an n-type layer disposed adjacent to the p-type layer, a dielectric layer positioned on one surface of the semiconductor substrate, a protective layer positioned on one surface of the dielectric layer, a first electrode electrically connected to the p-type layer of the semiconductor substrate, and a second electrode electrically connected to the n-type layer of the semiconductor substrate.

In one embodiment, the first electrode may have a plurality of contact portions which contact the semiconductor substrate through a portion of the dielectric layer and a portion of the protective layer, wherein the contact portions may be discontinuous with one another.

In one embodiment, the protective layer may include at least one of diamond-like carbon (“DLC”), hydrogenated amorphous carbon (a-C:H), i-carbon, Si-incorporated DLC, tetrahedral amorphous carbon, and a combination thereof.

In one embodiment, the diamond-like carbon may have a ratio of sp³ carbon to sp² carbon (sp³ carbon/sp² carbon) of about 0.2 to about 0.9.

In one embodiment, the protective layer may include an atomic percentage of hydrogen of about 10 atom % to about 60 atom %.

In one embodiment, the protective layer may have a refractivity of about 1.2 to about 3.6 and hardness of about 1,000 Kgf/mm² to about 10,000 Kgf/mm². In addition, in one embodiment the protective layer may have a thickness of about 10 nm to about 10,000 nm.

In one embodiment, the solar cell may further include an auxiliary layer disposed between the protective layer and the first electrode.

In one embodiment, the auxiliary layer may include at least one of a semiconductor, an oxide, a nitride, an oxynitride and a combination thereof.

In one embodiment, the semiconductor may include amorphous silicon, the oxide may include at least one of aluminum oxide (Al₂O₃), silicon oxide (SiO₂) and titanium oxide (TiO₂ or TiO₄), the nitride may include silicon nitride (SiNₓ), and the oxynitride may include at least one of aluminum oxynitride (AION) and silicon oxynitride (SiON).

In one embodiment, the auxiliary layer may have a thickness of about 10 nm to about 1,000 nm.

According to another aspect of this disclosure, an embodiment of a method of manufacturing a solar cell includes; providing a semiconductor substrate including a p-type layer and an n-type layer, providing a dielectric layer on one surface of the semiconductor substrate, providing a protective layer on one surface of the dielectric layer, patterning the dielectric layer and the protective layer, contacting a first electrode to the semiconductor substrate through one surface of the dielectric layer and one surface of the protective layer, and providing a second electrode on another surface of the semiconductor substrate.

In one embodiment, the protective layer may include at least one of diamond-like carbon, hydrogenated amorphous carbon, i-carbon, Si-incorporated DLC, tetrahedral amorphous carbon and a combination thereof.

In one embodiment, the protective layer may be provided by at least one of ion plating, arc deposition, plasma enhanced chemical vapor deposition (“PECVD”), radio frequency chemical vapor deposition (“RFCVD”), plasma impulse chemical vapor deposition (“PICVD”), ion beam sputtering, and laser ablation.

In one embodiment, the material for the diamond-like carbon may include at least one of methane (CH₄), acetylene (C₂H₂), benzene (C₆H₆), a solid-phase graphite and a combination thereof as a raw material.

In one embodiment, the protective layer may be formed at a temperature of about 20° C. to about 450° C.

In one embodiment, the method may further include providing an auxiliary layer on one surface of the protective layer after the providing a protective layer on one surface of the dielectric layer.

Other aspects of this disclosure will be described in the following detailed description.

### BRIEF DESCRIPTION OF THE DRAWINGS

The above and other aspects, advantages and features of this disclosure will become more apparent by describing in further detail exemplary embodiments thereof with reference to the accompanying drawings, in which:

FIG. 1 is a cross-sectional view of an exemplary embodiment of a solar cell according to the disclosure; and

FIGS. 2A to 2H are cross-sectional views that sequentially show an exemplary embodiment of a process of manufacturing the exemplary embodiment of a solar cell according to the disclosure.

### DETAILED DESCRIPTION OF THE INVENTION

Exemplary embodiments of this disclosure will hereinafter be described more fully hereinafter with reference to the following accompanied drawings, in which embodiments of the disclosure are shown. This disclosure may, however, be embodied in many different forms and should not be construed as limited to the embodiments set forth herein. Rather, these embodiments are provided so that this disclosure will be thorough and complete, and will fully convey the scope of the disclosure to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present disclosure.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present disclosure are described herein with reference to cross section illustrations that are schematic illustrations of idealized embodiments of the present disclosure. As such, variations from the shapes of the illustrations as a result, for example, of manufacturing techniques and/or tolerances, are to be expected. Thus, embodiments of the present disclosure should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present disclosure.

All methods described herein can be performed in a suitable order unless otherwise indicated herein or otherwise clearly contradicted by context. The use of any and all examples, or exemplary language (e.g., “such as”), is intended merely to better illustrate the disclosure and does not pose a limitation on the scope of the disclosure unless otherwise claimed. No language in the specification should be construed as indicating any non-claimed element as essential to the practice of the disclosure as used herein.

Hereinafter, the present disclosure will be described in detail with reference to the accompanying drawings.

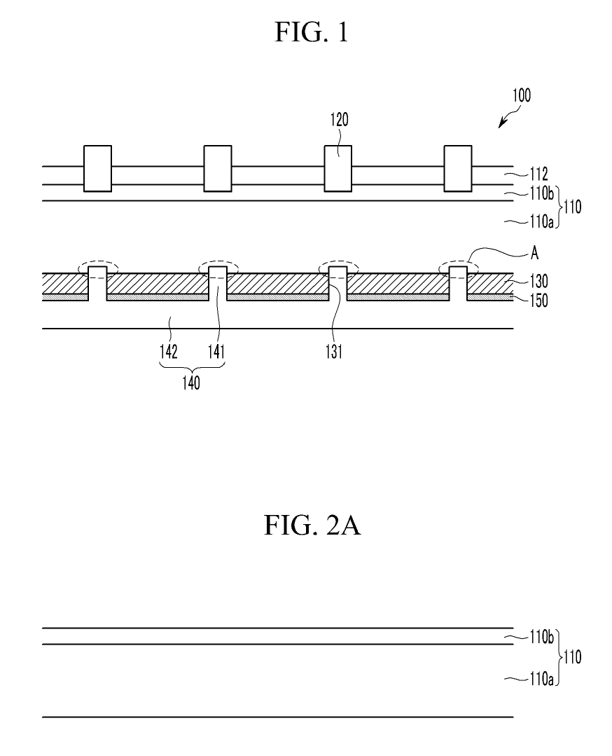

First, an embodiment of a solar cell 100 according to this disclosure is described with reference to FIG. 1.

FIG. 1 is a cross-sectional view of an embodiment of a solar cell according to the disclosure.

Hereinafter, for the better understanding and ease of description, the relationship between the upper and lower positions of the solar cell is described using the center of the semiconductor substrate 110 as a reference position, but the present disclosure is not limited thereto.

Referring to FIG. 1, the exemplary embodiment of a solar cell 100 according to the disclosure includes a semiconductor substrate 110 including a lower semiconductor layer 110a and an upper semiconductor layer 110b.

Embodiments of the semiconductor substrate 110 may be made of crystalline silicon, compound semiconductor or other similar materials. If the semiconductor substrate 110 is made of crystalline silicon, it may include, for example, a silicon wafer. Embodiments include configurations wherein one of the lower semiconductor layer 110a and the upper semiconductor layer 110b may be a semiconductor layer doped with a p-type impurity, and the other of the lower semiconductor layer 110a and the upper semiconductor layer 110b may be a semiconductor layer doped with an n-type impurity such that the lower semiconductor layer 110a and the upper semiconductor layer 110b are differently doped. The p-type impurity may include a Group III compound such as boron (B) or other similar material, and the n-type impurity may be a Group V compound such as phosphorus (P) or other similar material.

In one embodiment, the semiconductor substrate 110 may have a textured surface. The semiconductor substrate 110 with the textured surface may have protrusions and depressions, such as depressions or protrusion having a pyramid shape, or a porous structure such as a honeycomb structure. The semiconductor 110 having the textured surface may increase the amount of light absorbed into a solar cell 100 by increasing light scattering therewithin and thereby effectively lengthening a light absorption path within the semiconductor 110 while reducing reflectance of incident light from the surface of the semiconductor 110.

An insulation layer 112 is formed on the semiconductor substrate 110. Embodiments of the insulation layer 112 may be made of an insulating material that absorbs less light than the semiconductor substrate 110, and for example, it may include silicon nitride (SiNₓ), silicon oxide (SiO₂), titanium oxide (TiO₂), aluminum oxide (Al₂O₃), magnesium oxide (MgO), cerium oxide (CeO₂), other materials having similar characteristics and a combination thereof. Embodiments include configurations wherein the semiconductor substrate 110 may be formed in a single layer or a plurality of layers. Embodiments of the insulation layer 112 may have a thickness of, for example, about 200 Å to about 1,500 Å.

The insulation layer 112 may act as an anti-reflective coating to decreasing the reflectance of light on the surface of solar cell 100 and increase the absorption-selectivity of a certain wavelength region within the solar cell 100, and simultaneously improve the contact characteristics of additional layers to the silicon present on the surface of the semiconductor substrate 110 to increase the efficiency of the solar cell 100.

A plurality of front electrodes 120 are formed on the insulation layer 112. The front electrodes 120 extend along one direction of the semiconductor substrate 110 substantially in parallel, and penetrate the insulation layer 112 to contact the upper semiconductor layer 110b. The front electrode 120 may be made of a metal having relatively low resistivity compared to the other components of the solar cell 100, embodiments of such metals may include silver (Ag), and may be designed into a grid pattern in order to reduce shadowing loss and sheet resistance.

Embodiments include configurations wherein a front bus bar electrode (not shown) is formed on the front electrode 120. The bus bar electrode is to connect the solar cells adjacent to each other during assembly of a plurality of solar cells.

A dielectric layer 130 and a protective layer 150 are sequentially formed on the lower part of the semiconductor substrate 110. The dielectric layer 130 and protective layer 150 are patterned to provide a plurality of penetrating parts 131 (the penetrating parts 131 may also be referred to as grooves). The semiconductor substrate 110 is contacted with a rear electrode 140 through the plurality of penetrating parts 131. The dielectric layer 130 prevents current leakage as well as a recombination of charges to increase the efficiency of the solar cell 100.

Embodiments of the dielectric layer 130 may include a material selected from the group consisting of an oxide, a nitride, an oxynitride and a combination thereof; embodiments of the oxide may include aluminum oxide (Al₂O₃), silicon oxide (SiO₂), titanium oxide (TiO₂ or TiO₄) or other similar materials; embodiments of the nitride may include silicon nitride (SiNₓ) or other similar materials; and embodiments of the oxynitride may include aluminum oxynitride (AION), silicon oxynitride (SiON) or other similar materials, but is not limited thereto.

In one embodiment, the dielectric layer 130 may have a thickness of about 10 nm to about 1,000 nm. In one embodiment the thickness of the dielectric layer 130 may be about 50 nm to about 300 nm.

The protective layer 150 has excellent chemical stability and mechanical characteristics, and therefore it is possible to prevent damage to the dielectric layer 130 and to control refractivity to have a wide value range. Thereby, the protective layer 150 increases internal reflectance of the rear surface to improve the efficiency of the solar cell 100.

Embodiments of the protective layer 150 may include diamond-like carbon (“DLC”), hydrogenated amorphous carbon (“a-C:H”), i-carbon, Si-incorporated DLC, tetrahedral amorphous carbon, other materials with similar characteristics and a combination thereof. Embodiments include configurations wherein the protective layer 150 may be doped with fluorine, nitrogen, silicon, tungsten and other materials with similar characteristics, as applicable in order to improve the characteristics of the protective layer 150.

The DLC included in the protective layer 150 may have a fraction of sp³ carbon to sp² carbon (sp³ carbon/sp² carbon) of about 0.2 to about 0.9, and for example, of about 0.3 to about 0.7, or of about 0.4 to about 0.6. When the DLC has a fraction of sp^{a} carbon to sp² carbon (sp³ carbon/sp² carbon) within the range, it is possible to provide excellent mechanical stability and high durability so as to effectively improve the life characteristic of the solar cell 100. In addition, it is possible to control chemical stability, mechanical properties, and optical characteristics of the protective layer including the DLC by adjusting the fraction of sp³ carbon to sp² carbon of DLC.

Embodiments of the protective layer 150 may include an atomic percentage of hydrogen at about 10 atom % to about 60 atom %. Embodiments also include configurations having an atomic percentage of hydrogen at about 20 atom % to about 50 atom %. Embodiments also include configurations having an atomic percentage of hydrogen at about 20 atom % to about 40 atom %. When the hydrogen amount in the protective layer 150 is within the above specified ranges, it is possible to provide excellent thermal stability and to effectively improve the life-span characteristic, i.e., the operational life-span, of the solar cell 100 in which the protective layer 150 is disposed. In addition, it is possible to control the chemical stability, mechanical properties, and optical characteristic of the protective layer 150 by adjusting the amount of hydrogen in the protective layer 150.

In one embodiment, the protective layer 150 may have refractivity of about 1.2 to about 3.6. Embodiments also include configurations having a refractivity of about 1.5 to about 3.0. Embodiments also include configurations having a refractivity of about 1.8 to about 2.6. When the protective layer 150 has a refractivity within the above specified range, the internal reflectance of a rear surface of solar cell 100 is effectively increased to improve the efficiency of the solar cell 100.

In one embodiment, the protective layer 150 may have hardness of about 1,000 Kgf/mm² to about 10,000 Kgf/mm². Embodiments also include configurations having a hardness of about 2,000 Kgf/mm² to about 8,000 Kgf/mm². Embodiments also include configurations having a hardness of about 4,000 Kgf/mm² to about 8,000 Kgf/mm². When the protective layer 150 has a hardness within the above specified range, it is possible to improve a durability of the protective layer 150 to exterior impact. Thereby, damage to the dielectric layer 130 is effectively prevented to improve the life-span characteristics of the solar cell 100.

In one embodiment, the protective layer 150 may have a thickness of about 10 nm to about 10,000 nm. In one embodiment, the protective layer 150 may have a thickness of about 100 nm to about 5,000 nm. In another embodiment, the protective layer may have a thickness of about 200 nm to about 1,000 nm. When the protective layer 150 has a thickness within the above specified range, it is possible to provide the solar cell 100 with excellent durability and to improve rear-side reflectivity.

In addition, the efficiency of the solar cell 100 may be improved by adjusting the thickness of the dielectric layer 130 and protective layer 150 together to increase the reflectance of the rear surface of the solar cell 100 and to increase the short-circuit current (I_{sc}) of the solar cell 100, e.g., the current level at which the solar cell 100 will short-circuit.

A rear electrode 140 is formed on the lower part of the dielectric layer 130 and the protective layer 150. Embodiments of the rear electrode 140 may be made of an opaque metal such as aluminum (Al) or other materials with similar characteristics, and may have a thickness of about 2 μm to about 50 μm.

The rear electrode 140 includes a plurality of contact portions 141 contacting the lower semiconductor layer 110a through a penetrating part 131, and an entire surface part 142 formed on substantially the entire surface of the lower semiconductor layer 110a.

The contact portion 141 of the rear electrode 140 is a portion for forming a back surface field (“BSF”) A where aluminum acts as a p-type impurity when silicon is contacted with aluminum to provide an internal electric field therebetween, so it prevents electrons from moving toward the back surface of the solar cell 100. Thereby, it is possible to prevent the undesired recombination of charge carriers, such as holes and electrons, and the disappearance of charges into the back surface, so as to increase the efficiency of the solar cell 100.

The contact portion 141 of the rear electrode 140 that forms the back surface field A may be formed to be discontinuous. Exemplary embodiments include configurations in a shape of dot, sheet, stripe or other similar patterns.

By forming the patterned dielectric layer 130 on the lower part of semiconductor substrate 110, the recombination of charges is prevented, and one part of rear electrode 140 is contacted with the semiconductor substrate 110 to provide a BSF A and to increase the efficiency of the solar cell 100. In addition, damage to the dielectric layer 130 due to formation of the rear electrode 140 is prevented and the durability of the solar cell 100 is improved by forming the protective layer 150 on the lower part of the dielectric layer 130, so the life-span characteristic of the solar cell is improved. Light leakage is prevented by reflecting light passing through the semiconductor substrate 110 back into the semiconductor substrate 110, so as to increase the efficiency of the solar cell 100.

In addition, the entire surface part 142 of the rear electrode 140 reflects light passing through the semiconductor substrate 110 back into the semiconductor substrate 110 in order to prevent light leakage and to increase efficiency.

Embodiments include configurations wherein a rear bus bar electrode (not shown) is formed on the lower part of the rear electrode 140. In embodiments wherein it is present, the rear bus bar electrode is to connect solar cells adjacent to each other while assembling a plurality of solar cells, and includes, for example, silver (Ag), aluminum (Al), other materials with similar characteristics or a combination thereof.

Embodiments of the solar cell 100 may further include an auxiliary layer (not shown) between the protective layer 150 and the rear electrode 140. In embodiments where it is included, the auxiliary layer improves adhesion between the protective layer 150 and the rear electrode 140 to prevent a peel-off phenomenon between the protective layer 150 and the rear electrode 140.

Embodiments of the auxiliary layer may include a semiconductor, an oxide, a nitride, an oxynitride, other materials having similar characteristics and a combination thereof; embodiments of the semiconductor may include amorphous silicon or other materials having similar characteristics; embodiments of the oxide may include aluminum oxide (Al₂O₃), silicon oxide (SiO₂), titanium oxide (TiO₂ or TiO₄) or other materials having similar characteristics; embodiments of the nitride may include silicon nitride (SiNₓ) or other materials having similar characteristics; and embodiments of the oxynitride may include aluminum oxynitride (AlON), silicon oxynitride (SiON) or other materials having similar characteristics, but the disclosure is not limited thereto.

In one embodiment, the auxiliary layer may have a thickness of about 10 nm to about 1,000 nm. In another embodiment the auxiliary layer may have a thickness of about 50 nm to about 800 nm. In one embodiment, the auxiliary layer may have a thickness of about 50 nm to about 500 nm. In embodiments wherein the auxiliary layer has a thickness within the above specified range, it is possible to provide the solar cell 100 with an excellent passivation characteristic and to improve the rear side reflectance thereof.

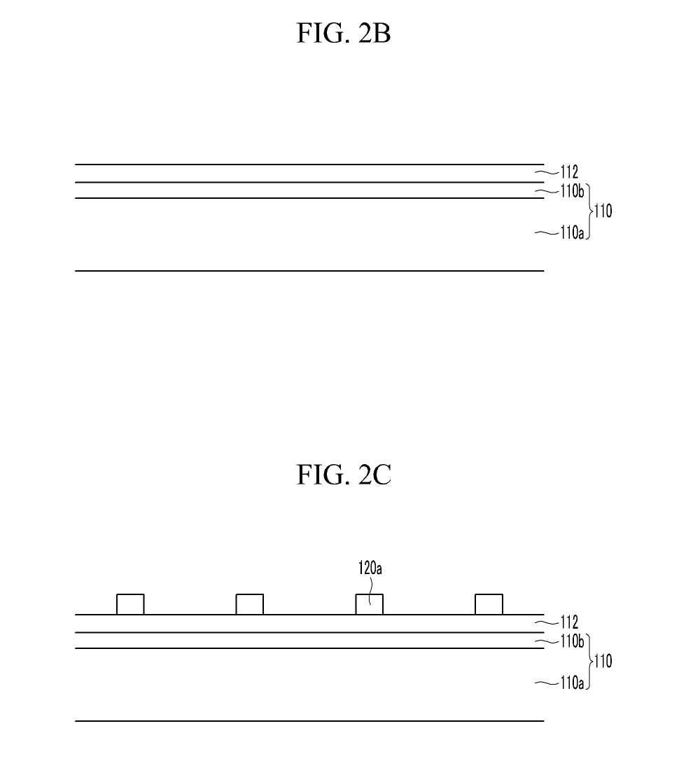

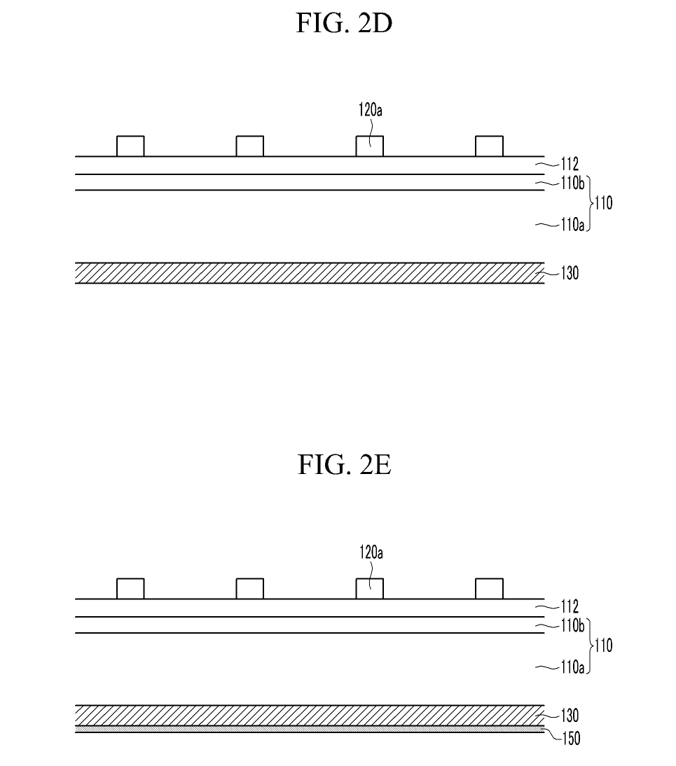

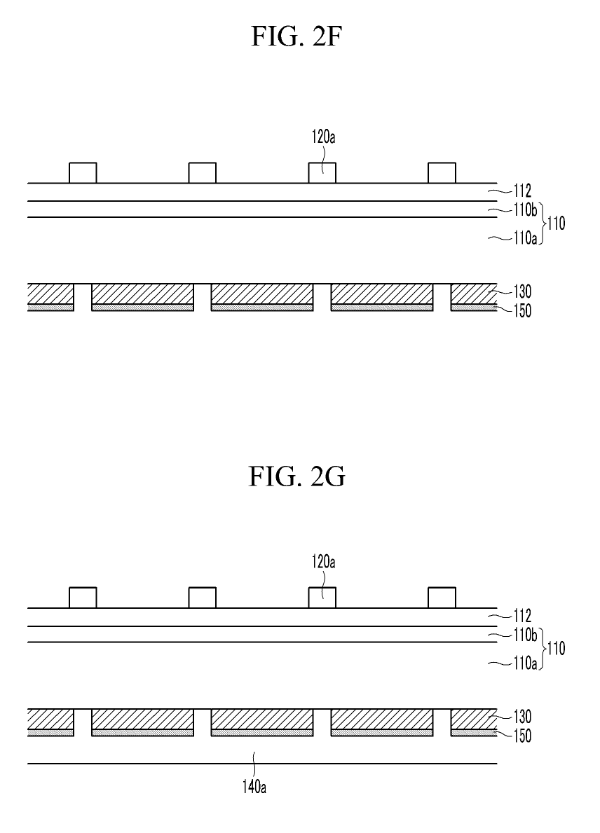

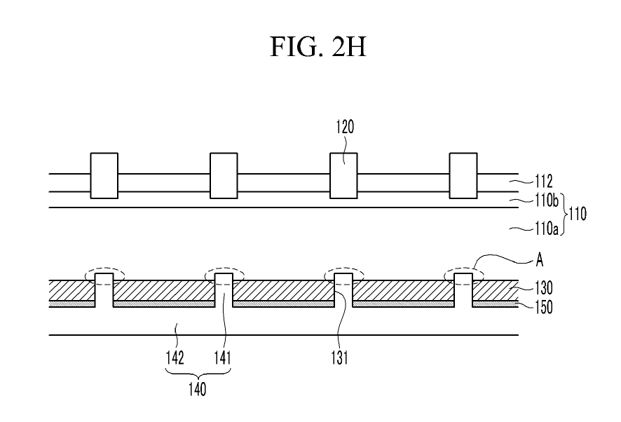

Hereinafter, an exemplary embodiment of a method of manufacturing an embodiment of a solar cell according to this disclosure is described with reference to FIG. 2A to FIG. 2H.

FIGS. 2A to 2H are cross-sectional views that sequentially show an exemplary embodiment of a process of manufacturing an embodiment of a solar cell as described above.

First, a semiconductor layer 110, for example a silicon wafer, is prepared. The semiconductor layer 110 may be doped with a p-type impurity, for example.

Then the semiconductor layer 110 is subjected to a surface texturing treatment. The surface-texturing treatment may be performed by a wet method using a strong acid, embodiments of which include nitric acid, hydrofluoric acid and other similar substances, or a strong base, embodiments of which include sodium hydroxide or other similar substance, or by a dry method using plasma.

Then referring to FIG. 2A, the semiconductor layer 110 is doped with an n-type impurity, for example. The n-type impurity may be doped by diffusing POCl₃, H₃PO₄, or other similar substances into the semiconductor layer 110 at a high temperature. After the doping, the semiconductor layer 110 includes a lower semiconductor layer 110a and an upper semiconductor layer 110b doped with different impurities from each other.

As shown in FIG. 2B, an insulation layer 112 is formed on the semiconductor layer 110. In one embodiment, the insulation layer 112 may be formed with, for example, silicon nitride, by PECVD.

As shown in FIG. 2C, a front electrode conductive paste 120a is formed on the insulation layer 112. In one embodiment, the front electrode conductive paste 120a may be formed by a screen printing method. The screen printing method includes coating a front electrode conductive paste 120a including metal powder such as silver (Ag) on the position to be formed with an electrode and drying the same. However, the present disclosure it is not limited thereto, and alternative methods of forming the front electrode 120 include Inkjet printing or press printing.

The front electrode conductive paste 120a is then dried. In one embodiment, the drying may be performed at about 150° C. to about 400° C.

A front bus bar electrode (not shown) may be formed on the front electrode conductive paste 120a.

Then, referring to FIG. 2D, the dielectric layer 130 is formed on the lower surface of the semiconductor layer 110, specifically the lower surface of the lower semiconductor layer 110a, and embodiments of the dielectric layer 130 may include, for example, an oxide such as aluminum oxide (Al₂O₃), silicon oxide (SiO₂), and titanium oxide (TiO₂ or TiO₄); a nitride such as silicon nitride (SiNₓ); an oxynitride such as aluminum oxynitride (AlON) and silicon oxynitride (SiON); or a combination thereof as discussed at length above. Embodiments of the dielectric layer 130 may be formed by a method such as vacuum deposition, spin coating, or other similar methods.

Referring to FIG. 2E, a protective layer 150 is provided under the dielectric layer 130, and the protective layer 150 may include, for example, DLC, hydrogenated amorphous carbon, i-carbon, Si-incorporated DLC, tetrahedral amorphous carbon, a combination thereof or other materials with similar characteristics. The protective layer 150 may be provided by ion plating, arc deposition, PECVD, radio frequency chemical vapor deposition (“RFCVD”), plasma impulse chemical vapor deposition (“PICVD”), ion beam sputtering, laser ablation, a combination thereof or other similar methods, but the method is not limited thereto.

When the protective layer 150 including the DLC is formed in accordance with the above described method, it is possible to control the hydrogen content, refractivity, hardness, and fraction of sp³ carbon to sp² carbon of the DLC included in the protective layer 150 by adjusting the raw materials and the process conditions.

For example, when the protective layer 150 including DLC is formed by arc deposition, the raw material may include a hydrocarbon such as methane (CH₄), acetylene (C₂H₂), and benzene (C₆H₆), a solid-phase graphite, or a combination thereof. The composition of the protective layer 150 may be controlled by adjusting the gas atmosphere, as required. Thereby, it is possible to control the hydrogen content, refractivity, hardness, and fraction of sp³ carbon to sp² carbon of the DLC included in the protective layer 150.

In one embodiment, the protective layer 150 may be formed at a temperature of about 20° C. to about 450° C. In one embodiment, the protective layer 150 may be formed at a temperature of about 25° C. to about 300° C. In one embodiment, the protective layer 150 may be formed at a temperature of about 25° C. to about 200° C. Since the protective layer 150 is formed at a low temperature, it is possible to stably provide a solar cell 100 having a high efficiency and to save heating associated manufacturing costs while fabricating the solar cell.

Although it is not shown, the solar cell 100 may further include an auxiliary layer on the lower part of the protective layer 150. Embodiments include configurations wherein the auxiliary layer may be formed by vacuum deposition, spin coating, or other similar methods.

Hereinafter, referring to FIG. 2F, the dielectric layer 130 and the protective layer 150 are patterned. Embodiments include configurations wherein the patterning may be performed using a laser, an etching paste, photolithography, or other similar methods, but the disclosure is not limited thereto.

Subsequently, referring to FIG. 2G to FIG. 2H, a rear electrode conductive paste 140a is formed on the lower part of the patterned protective layer 150 and the dielectric layer 130. In one embodiment, the rear electrode conductive paste 140a may be formed in accordance with the screen printing method. In such an embodiment, the screen printing includes coating a rear electrode conductive paste 140a including a metal powder such as aluminum (Al) on the entire surface of the lower part of the dielectric layer 130 and drying the same. However, the present disclosure is not limited thereto, and the method of forming the rear electrode conductive paste 140a may include Inkjet printing, pressing printing or other similar methods.

Subsequently, the rear electrode conductive paste 140a is dried. In one embodiment, the drying may be performed at a temperature of about 150° C. to about 400° C., for example.

As shown in FIG. 2H, while drying the front electrode conductive paste 120a and the rear electrode conductive paste 140a, the metal powder is permeated to reach the upper semiconductor layer 110b and the lower semiconductor layer 110a to provide a front electrode 120 and a rear electrode 140. At the contact portion between the rear electrode 140 and the lower semiconductor layer 110a, a plurality of BSF A is formed. The drying, i.e., firing, may be performed at a higher temperature than the melting temperature of the metal powder, and in one embodiment, for example, at a temperature of about 600° C. to about 1,000° C.

Then the rear bus bar electrode (not shown) may be formed on the lower part of the rear electrode 140.

In one embodiment, the front electrode conductive paste 120a and the rear electrode conductive paste 140a may include a metal powder, a glass frit, and an organic vehicle.

According to one embodiment of this disclosure, recombination of charges is prevented by providing a dielectric layer on the lower part of a semiconductor substrate, damage to the dielectric layer is prevented by providing a protective layer on the lower part of the dielectric layer, and the efficiency of a solar cell is increased by increasing the internal reflectance of the rear surface thereof. In addition, one part of the rear electrode penetrates the dielectric layer and the protective layer to provide a back surface field at the contact part with the semiconductor substrate. Thereby it is possible to increase the efficiency of the solar cell.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A solar cell comprising:
a semiconductor substrate comprising:
a p-type layer; and
an n-type layer disposed adjacent to the p-type layer;
a dielectric layer positioned on one surface of the semiconductor substrate;
a protective layer positioned on one surface of the dielectric layer;
a first electrode electrically connected to the p-type layer of the semiconductor substrate; and
a second electrode electrically connected to the n-type layer of the semiconductor substrate.

2. The solar cell of claim 1, wherein the first electrode includes a plurality of contact portions which contact the semiconductor substrate through a portion of the dielectric layer and a portion of the protective layer,
wherein the contact portions are discontinuous with one another.

3. The solar cell of claim 1, wherein the protective layer comprises at least one of diamond-like carbon, hydrogenated amorphous carbon, i-carbon, Si-incorporated diamond-like carbon, tetrahedral amorphous carbon and a combination thereof.

4. The solar cell of claim 3, wherein the diamond-like carbon has a sp^{a} carbon to sp² carbon ratio of about 0.2 to about 0.9.

5. The solar cell of claim 3, wherein the protective layer comprises an atomic percentage of hydrogen of about 10 atom % to about 60 atom %.

6. The solar cell of claim 1, wherein the protective layer has a refractivity of about 1.2 to about 3.6.

7. The solar cell of claim 1, wherein the protective layer has a hardness of about 1,000 Kgf/mm² to about 10,000 Kgf/mm².

8. The solar cell of claim 1, wherein the protective layer has a thickness of about 10 nm to about 10,000 nm.

9. The solar cell of claim 1, further comprising an auxiliary layer disposed between the protective layer and the first electrode.

10. The solar cell of claim 9, wherein the auxiliary layer comprises at least one of a semiconductor, an oxide, a nitride, an oxynitride and a combination thereof.

11. The solar cell of claim 10, wherein:
the semiconductor comprises amorphous silicon;
the oxide comprises at least one of aluminum oxide (Al₂O₃), silicon oxide (SiO₂) and titanium oxide (TiO₂ or TiO₄);
the nitride comprises silicon nitride (SiNₓ); and
the oxynitride comprises at least one of aluminum oxynitride (AlON) and silicon oxynitride (SiON).

12. The solar cell of claim 9, wherein the auxiliary layer has a thickness of about 10 nm to about 1,000 nm.

13. A method of manufacturing a solar cell, the method comprising:
providing a semiconductor substrate comprising:
a p-type layer; and
an n-type layer;
providing a dielectric layer on one surface of the semiconductor substrate;
providing a protective layer on one surface of the dielectric layer;
patterning the dielectric layer and the protective layer;
contacting a first electrode to the semiconductor substrate through one surface of the dielectric layer and one surface of the protective layer; and
providing a second electrode on another surface of the semiconductor substrate.

14. The method of claim 13, wherein the protective layer comprises one of diamond-like carbon, hydrogenated amorphous carbon, i-carbon, Si-incorporated diamond-like carbon, tetrahedral amorphous carbon and a combination thereof.

15. The method of claim 14, wherein the protective layer is provided by at least one of ion plating, arc deposition, plasma enhanced chemical vapor deposition, radio frequency chemical vapor deposition, plasma impulse chemical vapor deposition, ion beam sputtering, and laser ablation.

16. The method of claim 14, wherein the diamond-like carbon comprises at least one of methane (CH₄), acetylene (C₂H₂), benzene (C₆H₆), a solid-phase graphite and a combination thereof as a raw material.

17. The method of claim 13, wherein the protective layer is formed at a temperature of about 20° C. to about 450° C.

18. The method of claim 13, further comprising providing an auxiliary layer on one surface of the protective layer after the providing a protective layer on one surface of the dielectric layer.
